(19) United States
(12) Patent Application Publication
(10) Pub. No.: US 2006/0103017 A1
(43) Pub. Date: May 18, 2006

(54) Semiconductor device

(75) Inventors: Takamasa Usui, Tokyo (JP); Hideki Shibata, Yokohama-shi (JP); Tadashi Murofushi, Yokohama-shi (JP); Masakazu Jimbo, Yokohama-shi (JP); Hiroshi Hirayama, Yokohama-shi (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/033,994

(22) Filed: Jan. 13, 2005

(30) Foreign Application Priority Data
Nov. 12, 2004 (JP) 2004-328847

(51) Int. Cl. H01L 23/34

(52) U.S. Cl. 257/725

(57) ABSTRACT

A semiconductor device which comprises a wiring structure capable of reducing stress concentration at a boundary between a wiring and a low dielectric constant insulator even when the low dielectric constant insulator is used as an interlevel or interwiring insulator in a multilevel wiring, suppressing peeling-off of the insulator and having increased heat radiation efficiency is provided by comprising an insulator formed on a semiconductor substrate, a wiring formed in the insulator, and a network dummy formed in the insulator and disposed to be apart from the wiring.

### CROSS-REFERENCE TO RELATED APPLICATIONS

This application is based upon and claims the benefit of priority from prior Japanese Patent Application No. 2004-328847, filed Nov. 12, 2004, the entire contents of which are incorporated herein by reference.

### BACKGROUND OF THE INVENTION

1. Field of the Invention

The present invention relates to a wiring of semiconductor device, and more particularly to a semiconductor device comprising a multilevel wiring which uses a low dielectric constant insulator as an insulator.

2. Description of the Related Art

A semiconductor device uses low dielectric constant insulators as an interwiring insulator and an interlevel insulator in a multilevel wiring for the purpose of reducing a parasitic capacitance of the wiring to provide a higher speed operation and miniaturization. The low dielectric constant insulator has a dielectric constant lower than that of silicon oxide film (SiO₂ film), which has conventionally been used widely. For example, there are an organic silicon oxide film (SiOC film), a fluorine-added silicon oxide film (SiOF film), and an organic polymer insulator. These low dielectric constant insulators preferably have relative dielectric constant of 3 or lower.

Although the low dielectric constant insulators have characteristics of low dielectric constants compared with the SiO₂ film, the low dielectric constant insulators have deficiencies in mechanical strengths, e.g., low Young's moduli or low breaking strength. In the multilevel wiring, the low dielectric constant insulators are generally used for most of interlevel and interwiring insulators excluding an upper level insulator. It is because for a lower level closer to a semiconductor substrate, a parasitic capacitance between wirings or between wiring levels has a greater influence on performance of the semiconductor device.

The deficiency in the weak mechanical strength of the low dielectric constant insulator adversely affects not only a manufacturing process of the semiconductor device but also the performance thereof. For example, during chemical-mechanical polishing (CMP) generally used for planarization to form the multilevel wiring, problems occur such as formation of a dishing in a sparse wiring area, stress concentration at a boundary between the low dielectric constant insulator and the wiring, and/or peeling-off of the low dielectric insulator due to deformation thereof.

The formation of the dishing during the CMP is an old problem, and a method in which dummy patterns are formed in the sparse pattern area to suppress the dishing is disclosed in, e.g., Jpn. Pat. Appln. KOKAI Publication No. 10-335333. The dummy pattern is generally in an isolated rectangular shape.

Regarding stress concentration, when Young's moduli of materials used are compared with each other. For example, whereas Young's modulus of copper (Cu) as a wiring material is 150 GPa, that of the SiOC film as the low dielectric constant insulator is 2 to 20 GPa, i.e., a value of 1/10 or lower. Incidentally, Young's modulus of the SiO₂ film is 57 GPa. When a surface of the semiconductor substrate in which the wiring material (Cu) and the low dielectric constant insulator are coexisted is planarized by CMP, the softer low dielectric constant insulator is greatly displaced by polishing pressure, but little displacement occurs in the Cu which is a harder material. Consequently, large stress concentration occurs at the boundary between Cu and the low dielectric constant insulator, especially at a contact portion. The stress thus generated is not all released when the polishing is completed but partially frozen in the semiconductor device even after its completion. Therefore, during a reliability test or an operation of the semiconductor device in an end user, the frozen stress causes an increase in resistance of the wiring and/or the contact, or generates a void, consequently degrading reliability of the semiconductor device.

Additionally, as described above, when shear stress introduced by CMP processing becomes large, displacement of the low dielectric constant insulator is increased, causing a problem of the peeling-off the low dielectric constant insulator, in an extreme case. Jpn. Pat. Appln. KOKAI Publication No. 2004-79732 discloses a method of suppressing such peeling-off of the insulator. According to the method of the patent, insulator peeling-off is suppressed by stacking an insulator with a relative dielectric constant larger than a predetermined value on a surface of a low dielectric constant insulator, then forming a wiring and a dummy wiring in the stacked insulator. However, the structure in which the insulator with the large relative dielectric constant is stacked leads to increases in an effective relative dielectric constant of the overall insulator and the number of steps of a manufacturing process, which is not preferable.

Another deficiency of the low dielectric constant insulator is low thermal conductivity. When various materials used in the multilevel wiring are compared with one another for thermal conductivity, whereas thermal conductivity of Cu having good thermal conduction is 395 W/Km, thermal conductivity of SiO₂ and the low dielectric constant insulator are 2.03 W/Km and 0.1 to 0.5 W/Km, respectively. In other words, the thermal conductivity of the low dielectric constant insulator is about 1/1000 of that of the Cu, and about 1/10 of that of the SiO₂ film. In the semiconductor device, an amount of heat generated locally or entirely is increased with higher integration and/or higher speed operation. However, use of the low dielectric constant insulator deteriorates thermal conduction to the surface. Jpn. Pat. Appln. KOKAI Publication No. 2003-324103 discloses an example of measure for the problem. According to the patent, a protective film substantially consisted of a metal is formed on a semiconductor device surface above a multilevel wiring. The protective film is connected to a pad electrode disposed in an uppermost wiring level. Accordingly, heat radiation is improved during an operation of the semiconductor device. Furthermore, heat radiation effects are enhanced by forming a via for heat radiation independent of a wiring or a heat radiation wiring, or both. The method is effective for local heat radiation in the vicinity of the heat radiation via or the heat radiation wiring. However, no means is disclosed to efficiently lead heat generated in an active region or the wiring from the entire semiconductor device region to the protective film.

Therefore, there is a need for a semiconductor device which comprises a wiring structure capable of reducing stress concentration at a boundary between a wiring and a low dielectric constant insulator even when the low dielectric constant insulator is used as an interlevel insulator in a multilevel wiring, suppressing peeling-off of the insulator and having increased heat radiation efficiency.

### BRIEF SUMMARY OF THE INVENTION

According to one aspect of the present invention, a semiconductor device comprises an insulator formed on a semiconductor substrate, a wiring formed in the insulator, and a network dummy formed in the insulator and disposed to be apart from the wiring.

According to another aspect of the present invention, a semiconductor device comprises a first insulator formed on a semiconductor substrate, a first wiring formed in the first insulator, a first network dummy formed in the first insulator and disposed to be apart from the first wiring, a second insulator formed on the first insulator, a third insulator formed on the second insulator, a second wiring formed in the third insulator, a second network dummy formed in the third insulator and disposed apart from the second wiring, a connector formed in the second insulator to interconnect the first and second network dummies, and a protective film which covers the first and second wirings and the first, second and third insulators, and which is connected to at least one of the first or second network dummy.

### BRIEF DESCRIPTION OF THE SEVERAL VIEWS OF THE DRAWINGS

FIG. 1 is a view showing an example of a network dummy pattern according to a first embodiment of the present invention;

FIG. 2 is a sectional view of a typical wiring structure shown to explain a multilevel wiring structure;

FIG. 3 is a view illustrating stress concentration reduction effects by a dummy;

FIG. 4 is a view illustrating an effect of the dummy for suppressing displacement of a low dielectric constant insulator due to mechanical processing;

FIGS. 5 to 14 are views showing examples of other network dummy patterns according to the first embodiment;

FIG. 15 is a sectional view showing an example of a wiring structure according to a second embodiment of the invention; and

FIGS. 16 and 17 are sectional views showing wiring structures according to modifications of the second embodiment.

### DETAILED DESCRIPTION OF THE INVENTION

The variety of embodiments according to the present invention will be described in detail with reference to the accompanying drawings. Throughout the drawings, corresponding portions are denoted by corresponding reference numerals. The embodiments are only illustrative, and various changes and modifications can be made without departing from the spirit and scope of the invention.

### First Embodiment

A first embodiment of the invention is directed to a semiconductor device which comprises a wiring structure including a network dummy disposed in an interwiring insulator formed between wirings. By disposing the network dummy, even when a low dielectric constant insulator is used as an interlevel insulator in a multilevel wiring, it can be reduced stress concentration at a boundary between the wiring and the low dielectric constant insulator, and to suppress peeling-off of the insulator.

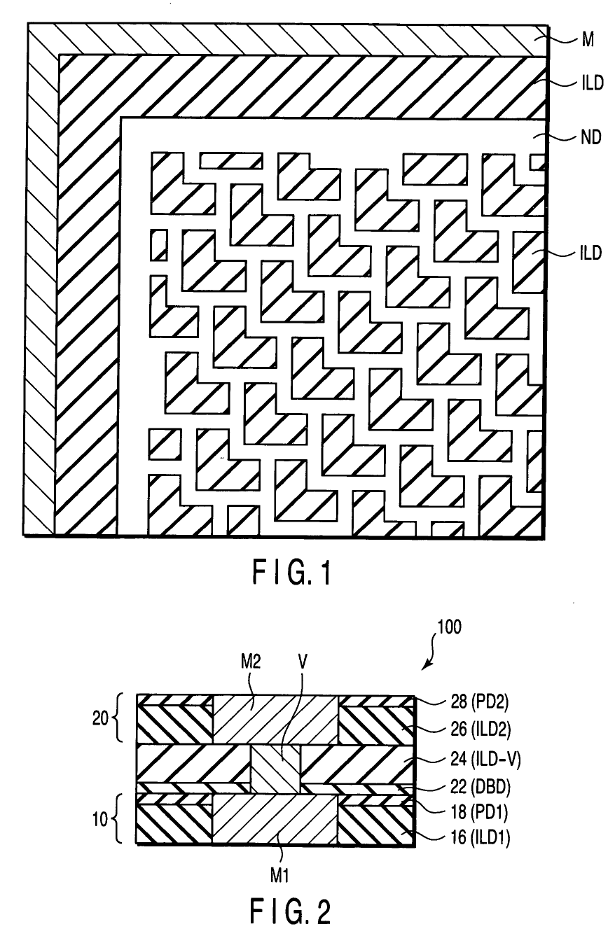

FIG. 1 is a plan view showing an example of a wiring level according to the embodiment. A white area is a network dummy ND, and an area with a thick oblique line is an interwiring insulator, e.g., a low dielectric constant insulator ILD. As the low dielectric constant insulator, for example, an organic silicon oxide film (SiOC film), a fluorine-added silicon oxide film (SiOF film), an organic polymer insulator, or a porous film thereof can be used. Additionally, a relative dielectric constant of the low dielectric constant insulator is preferably 3 or lower, more preferably 2 or lower.

FIG. 1 shows a corner of a wiring M bent at a right angle and an area of the inside of the corner thereof. The wiring M is formed in the low dielectric constant interwiring insulator ILD. In the low dielectric constant insulator ILD inside of the corner of the wiring M, a network dummy ND is formed apart from the wiring M. The network dummy ND constitutes a continuous network in a region surrounded with a wiring in one wiring level. In the network, an L-shaped low dielectric constant insulator ILD is arranged by being slightly shifted in position from another. Shifting amounts are set to be different in a vertical direction and a horizontal direction. As a result, when cut the network dummy ND in a random direction, the network dummy ND is formed to always include a boundary between itself and the low dielectric constant insulator ILD on a cut line. In other words, the low dielectric constant insulator ILD is divided into small portions by the network dummy ND. By forming the dummy into the network shape, in the CMP processing, for example, it can be reduced stress concentration by dispersing generated stress at the boundaries between the low dielectric constant insulators ILD and the dummies ND, and suppressed peeling-off of the low dielectric constant insulator ILD.

FIG. 2 shows an example of a sectional structure of a general multilevel structure 100 of the semiconductor device. In FIG. 2, the example of a 2-level wiring will be described. A first wiring level 10 disposed on a semiconductor substrate (not shown) includes a first interwiring insulator (ILD1) 16, a first protective insulator (PD1) 18 and a first wiring M1 formed in the insulators 16, 18. An interlevel insulator (ILD-V) 24 is formed over a diffusion preventive insulator (DBD) 22 on the first wiring level 10, and a via plug V is formed in the insulators 22, 24. The via plug V is a connector which connects the first wiring M1 to a second wiring M2 being formed thereabove. On the interlevel insulator (ILD-V) 24, a second wiring level 20 that includes a second interwiring insulator (ILD2) 26, a second protective insulator (PD2) 28 and the second wiring M2 is formed. Here, low dielectric constant insulators are used to the interwiring insulators (ILD1, ILD2) 16, 26 and the interlevel insulator (ILD-V) 24.

When the semiconductor device is miniaturized, a lower dielectric constant material is required for each insulator used in the multilevel wiring to achieve a higher speed operation by suppressing an increase in parasitic capacitance of the wiring, thus a mechanical strength of the insulator is accordingly lowered. For example, when a design rule miniaturization progresses by 2-generation from 100 nm to 50 nm, it is predicted that Young's modulus of the low dielectric constant insulator ILD will be reduced by about ⅓, and Young's moduli of the protective insulator PD and the diffusion preventive insulator DBD will be reduced by about 1/5. When average stress applied on a contact which is the boundary between the low dielectric constant insulator ILD and the wiring M is simulated, as a result of the miniaturization, stress is calculated to increase four times from about 20 MPa to about 80 MPa. It is predicted that reliability deterioration will occur when the stress of the contact of the semiconductor device becomes equal to/higher than 65 MPa.

It is known experimentally that an amount of the stress concentration depends on a space between the wirings M. However, it is not practical to form the wring M into any desired pattern. Thus, it can be reduced stress applied at the contact by forming a dummy in the interwiring insulator ILD. For the dummy, the same material as that of the wiring M, or a material having an equivalent mechanical strength with the wiring M is preferable.

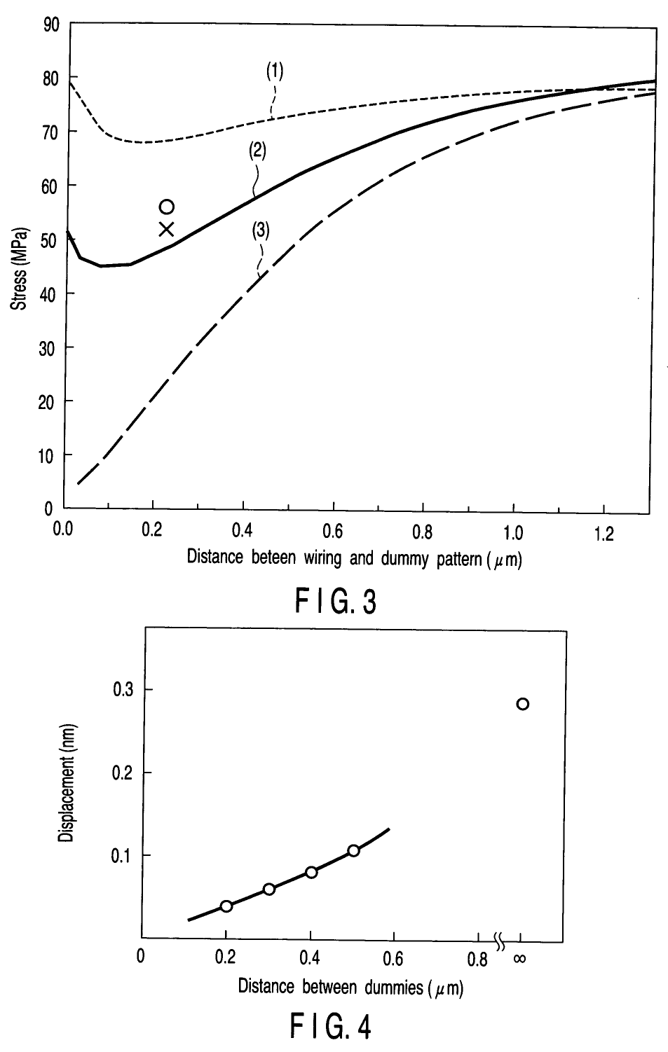

FIG. 3 shows a result of stress concentration simulating by changing a distance between the wiring M and the dummy in the 2-level wiring (M1 level, M2 level). A horizontal axis indicates a distance between the wiring M or the contact and the dummy, and a vertical axis indicates average stress at the boundary of the contact and the interwiring insulator ILD. Additionally, stresses are also calculated when the level constituting the dummy is changed. In FIG. 3, a dotted line (1) indicates a case in which a dummy is formed in one wiring level only (M1 level or M2 level), a solid line (2) indicates a case in which dummies are formed in both wiring levels (M1 level and M2 level), and a broken line (3) indicates a case in which dummies are formed in all the levels of both wirings (M1 level and M2 level) and the interlevel insulator (via level).

As apparent from FIG. 3, it is the case of the solid line (2) and the broken line (3) that may allow stress at the contact to 65 MPa or lower to prevent reliability deterioration. It is the case in which the dummies are formed at least in each of the wiring level (M1 level and M2 level). The structure of forming similar dummies in all the levels including the interlevel insulator (via level) (shown in the broken line (3)) is really effective for reducing stress. At present, however, it is considered difficult to apply the structure immediately because of increased constraints on wiring level designing. In the case of forming the dummy in each wiring level only, it can be understood from the solid line (2) of FIG. 3 that stress at the contact can be reduced to 65 MPa or lower by setting a distance between the dummy and the wiring M equal to/smaller than 0.5 μm. A more preferable distance is 0.1 to 0.2 μm in which a curve is in a minimum value. However, in the case of making the dummy of a conductive material such as a wiring material, when a distance between the dummy and the wiring M becomes equal to/smaller than 0.05 μm, a parasitic capacitance is increased to an amount that cannot be neglected. Thus, the distance between the dummy and the wiring M is preferably set from 0.05 μm to 0.5 μm.

Each line of FIG. 3 is a case in which a dummy is formed with an occupation ratio (referred to as coverage, hereinafter) of 100%, wherein the coverage is a ratio between the dummy portion in the insulator ILD and all of the dummy area including the dummy portion and insulator ILD. That is, the 100% coverage indicates that the dummy includes no insulator ILD inside. In FIG. 3, a cross indicates a case of reducing the coverage to 20%, and a circle indicates a case of 10%. Thus, even when the coverage is reduced to 10%, it can be achieved stress at the contact to 65 MPa or lower. Accordingly, the coverage of the dummy can be set to 10% or higher.

Whether the peeling-off of the low dielectric constant film occurs during processing by CMP or the like or not depends on displacement of the low dielectric constant insulator ILD. To suppress the peeling-off, displacement of the low dielectric constant insulator is preferably to be controlled below 0.15 nm. FIG. 4 shows a result of simulating displacement of the low dielectric constant insulator ILD when square dummy patters are arranged at different intervals in the low dielectric constant insulator ILD and shear stress such as caused during CMP processing is applied. A horizontal axis indicates a distance between the dummies, and a vertical axis indicates displacement of the low dielectric constant insulator ILD in a shear direction. A plot at a position corresponding to an infinite mark on the horizontal axis is a case of only the low dielectric constant insulator in which no dummy is arranged. In the case of the low dielectric constant insulator only, it can be understood that displacement approaches to 0.3 nm, thus peeling-off can easily be occurred to the low dielectric constant insulator ILD. Displacement of the low dielectric constant insulator ILD is reduced by disposing the dummy. From FIG. 4, it can be understood that the displacement of the low dielectric constant insulator ILD can be controlled below 0.15 nm when a space between the dummies is 0.5 μm or less.

In an actual CMP processing, since stress is applied in any directions within a plane, the low dielectric constant insulator ILD is preferably divided into sizes of 0.5 μm or smaller in any directions by the dummy.

The dummy that satisfies the aforementioned two requirements has a continuous network structure. In the network dummy ND, the low dielectric constant insulators ILD are not arranged in like a lattice pattern but preferably arranged to be shifted by a predetermined amount in a predetermined direction. That is, even when the network dummy ND is cut in a random direction, it is preferable that a boundary between the low dielectric constant insulator ILD and the network dummy ND is always presented on a cutting line. Furthermore, the low dielectric constant insulator ILD is preferably divided into sizes of 0.5 μm or smaller in any directions. In other words, between any two points, which are apart at least 0.5 μm each other and located within the network dummy area, it is preferable that a boundary between the low dielectric constant insulator ILD and the dummy ND is present between the two points, excluding a case in which the two points are on the network dummy ND and no boundary is existed between them.

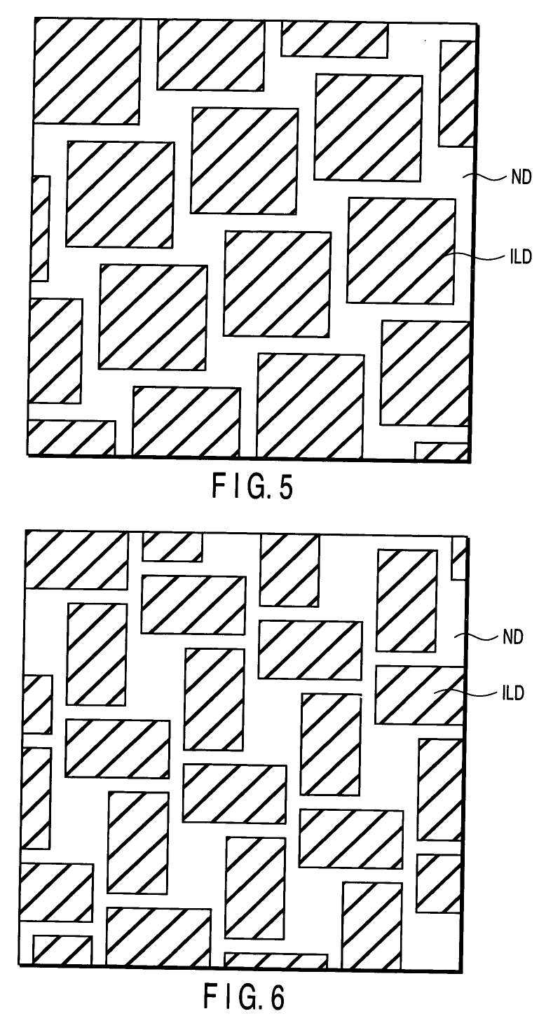

Such network dummies ND are infinitely present. Some examples other than illustrated in FIG. 1 are shown in FIGS. 5 to 14. In each of the drawings, a white area indicates the network dummy ND, and an oblique-line area indicates the low dielectric constant insulator ILD. A pattern of the network dummy ND is preferably a continuous network pattern consisting of a cyclic pattern with certain regularity from a standpoint of automatic pattern generation.

FIGS. 5 and 6 show examples of relatively simple patterns. In FIG. 5, one low dielectric constant insulator ILD is square and dispersed in the network dummy ND. The square shaped low dielectric constant insulators ILD are arranged in positions shifting in a horizontal direction and a vertical direction by different amounts each other to be provided with certain cyclicity. According to the example, coverage of the network dummy ND is relatively small, that is about 25%.

FIG. 6 shows a case in which a low dielectric constant insulator ILD is rectangular in shape. Long sides of rectangles are alternately arranged in vertical and horizontal directions, and shifted in a horizontal direction and a vertical direction by different amounts each other to be provided with certain cyclicity. By forming the network dummy ND in such a manner, when cutting the network dummy ND in any directions, at least one boundary between the network dummy ND and the low dielectric constant insulator ILD can always be presented on a cut line. Besides, by properly setting a pattern size, between two points which are apart at least 0.5 μm each other and located within the network dummy area, and at least one of which is not on the network dummy, it can be presented the boundary between the low dielectric constant insulator ILD and the dummy ND.

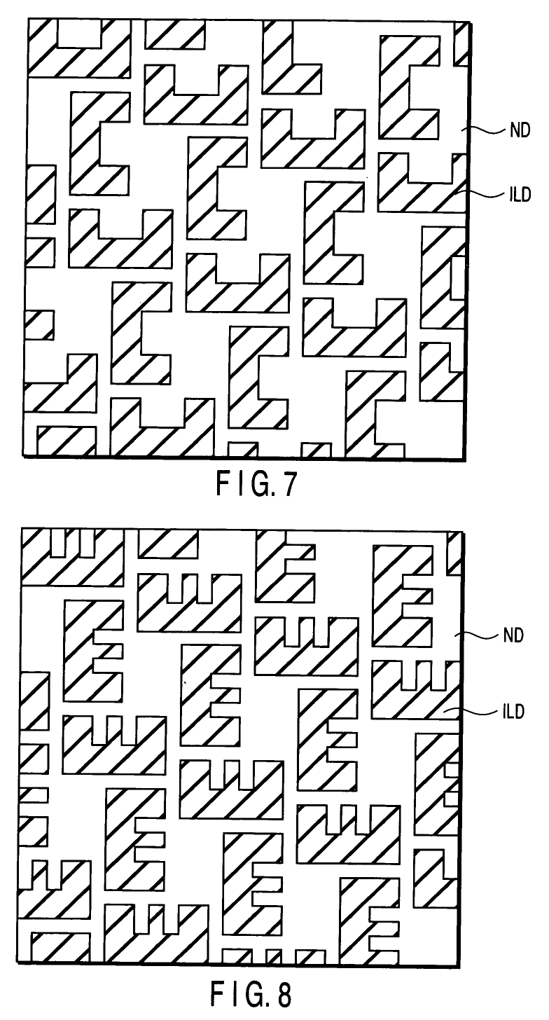

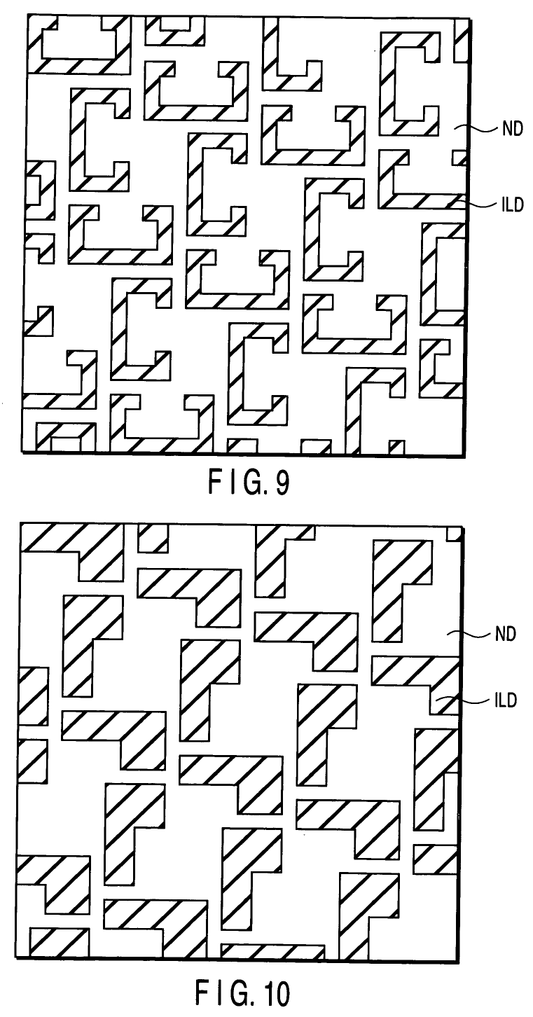

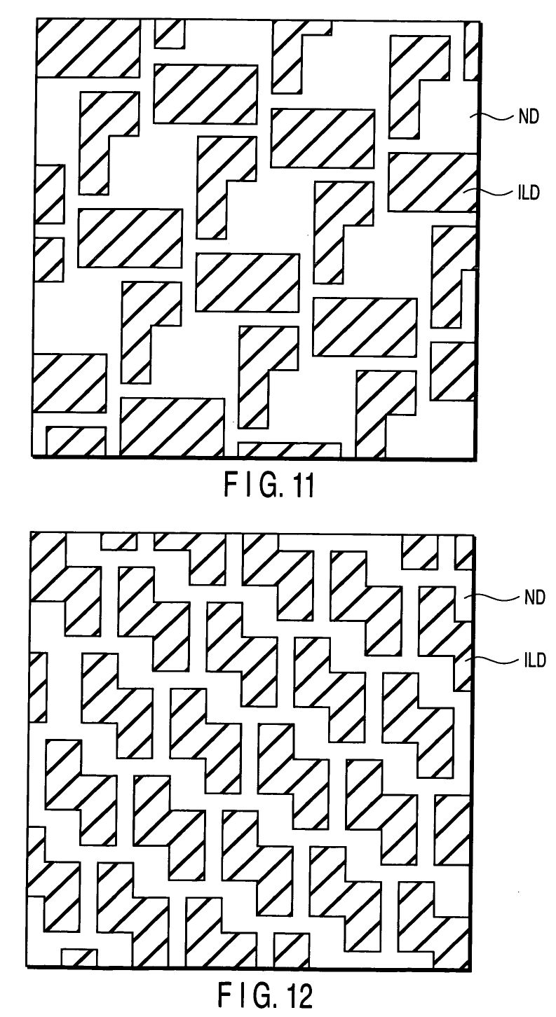

FIGS. 7 to 11 show modified examples of the pattern in FIG. 6. That is, a pattern of a rectangular low dielectric constant insulator ILD is arranged by removing a part thereof. FIG. 7 shows a case in which a center of a long side of a rectangle is removed and a low dielectric constant insulator ILD is formed into a U shape. FIG. 8 shows a case in which two places near a center of a long side of a rectangle are removed and a low dielectric constant insulator ILD is formed into an E shape. FIG. 9 shows a case in which a center of a rectangle is further removed and a low dielectric constant insulator ILD is formed into a C shape. Coverage of a network dummy ND shown in FIG. 9 is large, that is about 77%. FIG. 10 shows an example in which a pattern of a rectangular low dielectric constant insulator ILD is removed by about ¼ and the film is arranged in an L shape.

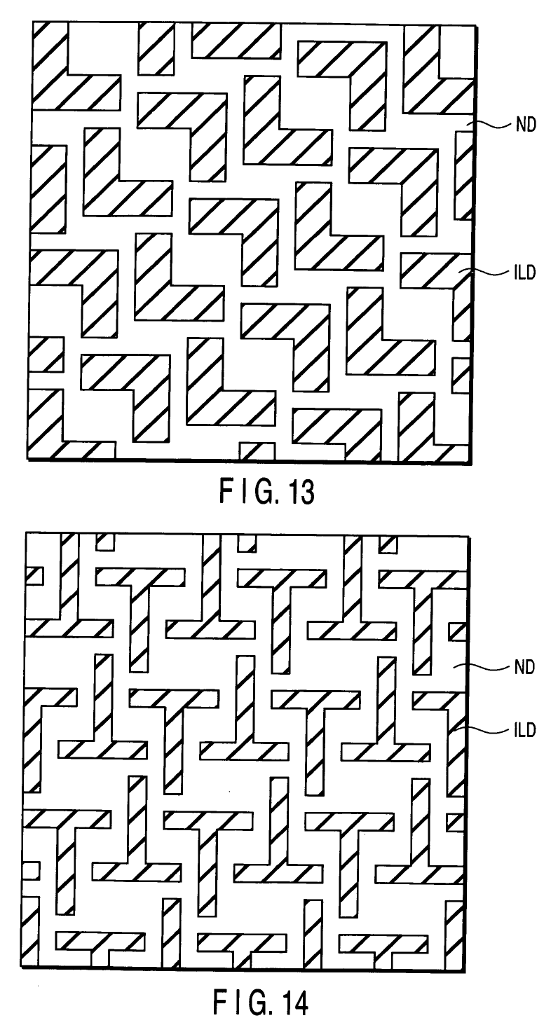

In the examples described above, the patterns of the low dielectric constant insulators ILD with one shape of a rectangle or a modified rectangle are alternately arranged by changing directions in the vertical and horizontal directions. However, it can be applied a combination of two or more shapes different in the longitudinal and horizontal directions. FIG. 11 shows an example in which a pattern of a rectangular low dielectric constant insulator ILD is arranged to be horizontally long and the L-shaped pattern in FIG. 10 is arranged to be vertically long.

As other examples with other shapes, FIG. 12 shows a zig-zag pattern arrangement in which patterns of square low dielectric constant insulators ILD are divided from the center and connected by being shifted. FIG. 13 is an arrangement in which L shape patterns with an equal length in horizontal and vertical directions are reversed one another. FIG. 14 shows an arrangement with T-shaped patterns.

Such patterns of network dummies ND, or patterns of low dielectric constant insulators ILD, are infinitely present. However, even when the same basic pattern is used, it is important to properly set its arrangement that is amounts of shifting in the horizontal and vertical directions. It should be noted when a pattern arrangement is erroneously set, the low dielectric constant insulator ILD cannot be divided into desired sizes by the network dummy ND.

As described above, according to the embodiment, by arranging the network dummy ND at least in the interwiring insulator of the wirings to meet the aforementioned requirements, it can be provides the semiconductor device comprising the wiring structure, which can reduce stress concentration in the boundary between the wiring M and the low dielectric constant insulator ILD and suppress peeling-off of the low dielectric constant insulator ILD, even when the low dielectric constant insulators are used for the interwiring insulator and the interlevel insulator.

### Second Embodiment

A second embodiment is directed to a semiconductor device which comprises a wiring structure for efficiently radiating heat generated in the semiconductor device. Specifically, there is provided a wiring structure in which by disposing a network dummy ND in each wiring level, interconnecting upper and lower network dummies by a connector, i.e., a via plug, and further disposing a protective film for heat radiation, thus stress of a low dielectric constant insulator is reduced, and heat generated in the semiconductor device is efficiently radiated therefrom. Especially, in a higher speed semiconductor device and/or a lower power consumption semiconductor device, heat radiation characteristics influence significantly on performance thereof.

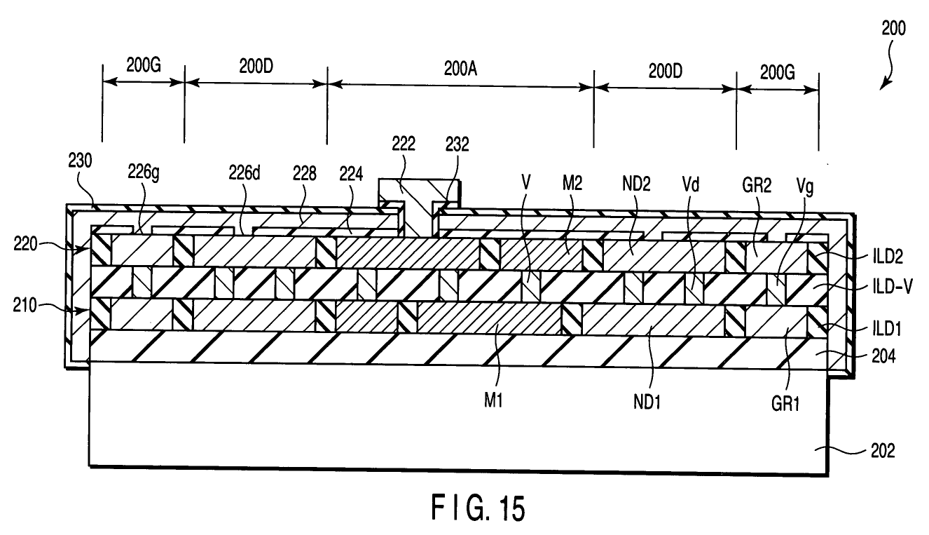

FIG. 15 is a sectional view showing an example of a wiring structure 200 of the embodiment. The drawing shows an example of a 2-level wiring. However, the structure is similar for multilevel wirings of 3 levels or more. A wiring region 200A, a network dummy region 200D and a guard ring region 200G are formed above a semiconductor substrate 202, e.g., a silicon substrate.

A first insulator 204 is formed to cover an active device (not shown) such as a metal oxide semiconductor field effect transistor (MOSFET) formed on the silicon substrate 202. A first wiring level 210 is being formed on the first insulator 204.

First, a first interwiring insulator ILD1 is formed on an entire surface of the first insulator 204. In the first interwiring insulator ILD1, a first wiring M1 and a first guard ring GR1 surrounding a specific device group are formed. A first network dummy ND1 is formed in a region between the first wiring M1 and the first guard ring GR1 in the first interwiring insulator ILD1. The first network dummy ND1 comprises a cyclic continuous network pattern similar to that of the first embodiment. The first wiring M1, the first guard ring GR1 and the first network dummy ND1 are preferably consisted of the same metallic materials such as copper (Cu). However, different materials can be used. In this case, a thermal conductive material having high thermal conductivity is used for the network dummy ND1. The first interwiring insulator ILD1 is preferably formed by a low dielectric constant insulator, but other insulators can be used. For the low dielectric constant insulator, for example, an organic silicon oxide film (SiOC film), a fluorine-added silicon oxide film (SiOF film), an organic polymer insulator, or a porous film thereof can be used. Additionally, a relative dielectric constant of the low dielectric constant insulator is preferably 3 or lower, more preferably 2 or lower.

A second wiring level 220 is formed via an interlevel insulator ILD-V on the first wiring level 210. The second wiring level 220 includes a second wiring M2, a second guard ring GR2 and a second network dummy ND2 formed in the second interwiring insulator ILD2, as in the case of the first wiring level 210. The first wiring Ml and the second wiring M2 are interconnected through a via plug V formed as a connector in the interlevel insulator ILD-V. Similarly, the first and second guard rings GR1, GR2 are interconnected through a via plug Vg, and the first and second network dummies ND1, ND2 are interconnected through a via plug Vd. A pad electrode 222 is formed on a part of the second wiring M2 to connect with the outside.

A protective film 228 is formed above the second wiring level 220 through a diffusion preventive insulator 224, e.g., a silicon nitride film (SiN film). The protective film 228 is connected to the second network dummy ND2 and the second guard ring GR2 through contacts 226d, 226g disposed in the diffusion preventive insulator 224. The protective film 228 provides a passivating function for preventing incursion of moisture or the like into the semiconductor device from the outside and a heat radiation function for radiating heat from the semiconductor device. Accordingly, as a material for the protective film 228, a metal with high thermal conductivity, e.g., aluminum (Al) or an aluminum alloy, can be used. The Al or the Al alloy is preferable as a material for the protective film 228 since a stable oxide film 230, i.e., a passive film, can be formed on the surface by, e.g., an oxygen plasma treatment.

Since the network dummy ND of the embodiment is not only formed in the wiring level but also in the interlevel insulator ILD-V as the via plug Vd, the network dummy ND has effects for suppressing stress concentration and suppressing peeling-off of the low dielectric constant insulator equal to/more than those of the first embodiment. An excellent heat radiation function of the network dummy ND of the embodiment will be described below.

According to the embodiment, the network dummies ND with high thermal conductivity are almost uniformly and continuously formed in the entire wiring levels 210, 220. Thus, heat locally generated in an active device such as MOSFETs formed on the silicon substrate 202 and/or in the wirings M1, M2 or the like can be dispersed uniformly in the wiring level at first. The network dummies ND1 and ND2 in the wiring levels are interconnected through a connector with high thermal conductivity, i.e., the via plug Vd. Since the network dummies ND1, ND2 constitute a continuous network, the network dummies ND1 and ND2 can be interconnected even when the via plug Vd is formed without any place constraints. Thus, for example, heat generated in the MOSFETs formed on the silicon substrate 202 is collected by the first network dummy ND1 formed in the first wiring level 210, and dispersed therein. Further, the heat in the first network dummy ND1 is conducted through the via plug Vd to the second network dummy ND2 formed in the second wiring level 220, and conducted through the contact 226d to the protective film 228, then radiated to the outside of the semiconductor device.

As described above, according to the embodiment, it can be provided the semiconductor device comprising the wiring structure, which can reduce stress concentration in the boundary between the wiring and the low dielectric constant insulator and suppress peeling-off of the low dielectric constant insulator, even when the low dielectric constant insulators are used for the interwiring insulator and the interlevel insulator.

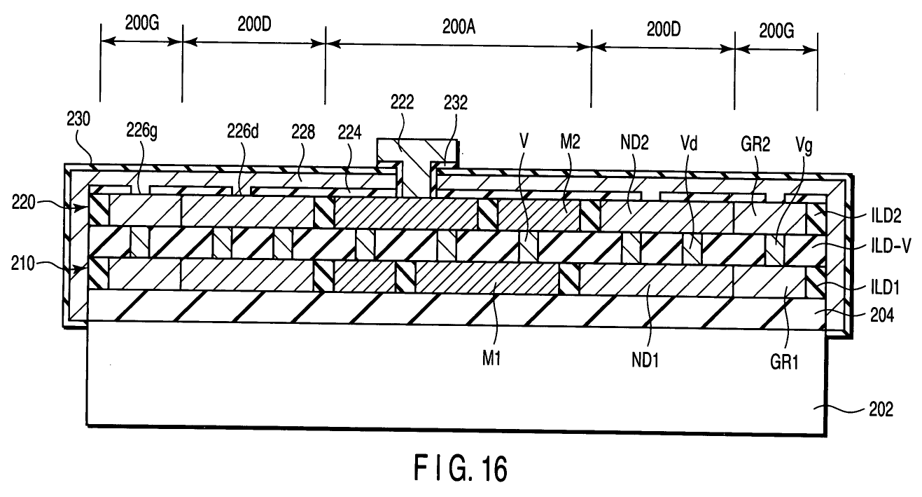

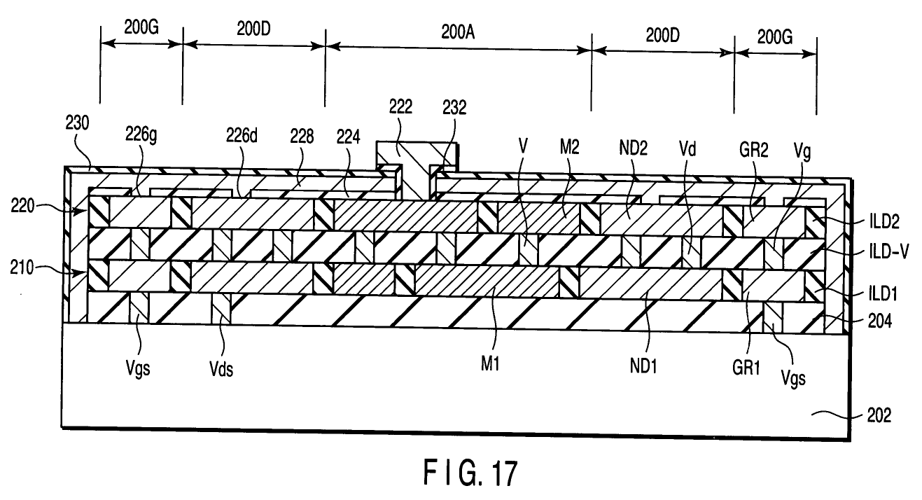

FIGS. 16 and 17 show modified examples of the second embodiment.

As shown in FIG. 16, the network dummies ND1, ND2 can be formed by being directly, i.e., continuously, connected to guard rings GR1, GR2 in each wiring level 210, 220. Since the guard rings GR1, GR2 and the via plug Vg are consisted of the same metallic materials as those of the wirings M1, M2, and the via plug V, a heat radiation effect can be enhanced more.

Further, FIG. 17 shows a structure in which the network dummy ND, the guard ring GR and/or the protective film 228 are connected to silicon substrate 202 through the via plugs Vds, Vgs or directly. By connecting to silicon substrate, heat from the semiconductor device can also be radiated through silicon substrate, and heat radiation efficiency can be enhanced more.

As described above, according to the present invention, it can be provided the semiconductor device comprising the wiring structure capable of reducing stress concentration in the boundary between the wiring and the low dielectric constant insulator and suppressing peeling-off of the insulator during processing by CMP or the like, and further increasing heat radiation efficiency, even when the low dielectric constant insulator is used for the interlevel insulator in the multilevel wiring.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general invention concept as defined by the appended claims and their equivalents.

What is claimed is:

1. A semiconductor device comprising:
an insulator formed above a semiconductor substrate;
a wiring formed in the insulator; and
a network dummy formed in the insulator and disposed to be apart from the wiring.

2. The semiconductor device according to claim 1, wherein the insulator is consisted of a low dielectric constant material, and the network dummy is consisted of a material whose mechanical strength is higher than that of the insulator.

3. The semiconductor device according to claim 2, wherein a boundary between the network dummy and the insulator is presented on a line in any directions in a network dummy area.

4. The semiconductor device according to claim 1, wherein a boundary between the network dummy and the insulator is presented on a line in any directions in a network dummy area.

5. The semiconductor device according to claim 4, wherein the network dummy is consisted of a metallic material.

6. The semiconductor device according to claim 4, wherein the boundary between the network dummy and the insulator is presented between any two points, which are apart at least 0.5 μm each other and located within the network dummy area, and at least one of which is not on the network dummy.

7. The semiconductor device according to claim 4, wherein the network dummy comprises a cyclic continuous network pattern.

8. The semiconductor device according to claim 1, wherein a boundary between the network dummy and the insulator is presented between any two points, which are apart at least 0.5 μm each other and located within a network dummy area, and at least one of which is not on the network dummy.

9. The semiconductor device according to claim 1, wherein a distance between the network dummy and the wiring is equal to/larger than 0.05 μm to equal to/smaller than 0.5 μm.

10. The semiconductor device according to claim 1, wherein the network dummy comprises a cyclic continuous network pattern.

11. A semiconductor device comprising:
a first insulator formed above a semiconductor substrate;
a first wiring formed in the first insulator;
a first network dummy formed in the first insulator and disposed to be apart from the first wiring;
a second insulator formed on the first insulator;
a third insulator formed on the second insulator;
a second wiring formed in the third insulator;
a second network dummy formed in the third insulator and disposed apart from the second wiring;
a connector formed in the second insulator to interconnect the first and second network dummies; and
a protective film which covers the first and second wirings and the first, second and third insulators, and which is connected to at least one of the first or second network dummy.

12. The semiconductor device according to claim 11, wherein a boundary between the first or second network dummy and the first or second insulator is presented on a line in any directions in a first or second network dummy area.

13. The semiconductor device according to claim 11, wherein a boundary between the first or second network dummy and the first or second insulator is presented between any two points, which are apart at least 0.5 μm each other and located within a first or second network dummy area, and at least one of which is not on the first or second network dummy.

14. The semiconductor device according to claim 11, wherein a distance between the first or second network dummy and the first or second wiring is equal to/larger than 0.05 μm to equal to/smaller than 0.5 μm.

15. The semiconductor device according to claim 11, wherein the first or second network dummy comprises a cyclic continuous network pattern.

16. The semiconductor device according to claim 11, wherein the first or second insulator is consisted of a low dielectric constant material, the first or second network dummy is consisted of a thermal conductive material whose mechanical strength is higher than that of the first or second insulator, and the connector and the protective film are consisted of thermal conductive materials.

17. The semiconductor device according to claim 16, wherein the first or second network dummy is consisted of a metallic material, and the protective film contains aluminum or an aluminum alloy.

18. The semiconductor device according to claim 16, wherein a boundary between the first or second network dummy and the first or second insulator is presented on a line in any directions in the first or second network dummy area.

19. The semiconductor device according to claim 16, wherein a distance between the first or second network dummy and the first or second wiring is equal to/larger than 0.05 μm to equal to/smaller than 0.5 μm.

20. The semiconductor device according to claim 16, wherein the first or second network dummy comprises a cyclic continuous network pattern.
